(19) United States
(12) Patent Application Publication
(10) Pub. No.: US 2002/0197854 A1
(43) Pub. Date: Dec. 26, 2002

(54) Selective deposition of materials for the fabrication of interconnects and contacts on semiconductor devices

(76) Inventors: Allen J. Bard, Austin, TX (US); Chong-Yang Liu, Austin, TX (US)

Correspondence Address: Edwin S. Flores, Gardere Wynne Sewell LLP, 3000 Thanksgiving Tower, 1601 Elm Street, Suite 3000, Dallas, TX, 75201-4767, US

(21) Appl. No.: 10/147,364

(22) Filed: May 16, 2002

Related U.S. Application Data
(60) Provisional application No. 60/291,503, filed on May 16, 2001.

(51) Int. Cl. H01L 21/4763; H01L 21/44

(52) U.S. Cl. 438/644; 438/654

(57) ABSTRACT

One form of the present invention is a method for mask-less selective deposition made up of the steps of contacting a first portion of a substrate with a chemical agent that binds to the substrate to affect the susceptibility of the portion of the substrate to deposition. Following the treatment with the chemical agent, a first layer of a first material is deposited on a second portion of the surface. The first and second portions of the substrate may in fact be the same portion. That is to say, that the chemical agent may enhance or inhibit the deposition of the material of a portion of the substrate.

This application claims priority from Provisional Application Serial No.: 60/291,503, filed on May 16, 2001.

The United States Government may own certain rights in this invention under National Science Foundation (NSF), Project Grant No. CHE9876855.

### BACKGROUND OF THE INVENTION

Selective deposition of materials to form interconnects and contacts for semiconductor devices is of great interest and importance. As the size of these devices continues to decrease, the ability to form the necessary electrical connections between the components that make up the devices becomes more and more difficult.

Additionally, the techniques that are currently being used to allow for the selective deposition of materials have, for the most part, used masks that form a physical barrier between the desired site of deposition and those areas where no deposition is desired. The preparation of these masks is often time consuming and technologically challenging, and there are physical limitations as to how small they can ultimately be made.

There is currently great interest in the semiconductor device manufacture industry related to the electrodeposition of copper as an interconnect metal. In the fabrication of devices, copper is often first deposited on a barrier layer material (such as tantalum oxide or titanium nitride) by a process like chemical vapor deposition, vacuum evaporation or sputtering. However such a treatment frequently leaves portions of the barrier layer with no copper deposits. Ideally, one would like to electrodeposit copper on the barrier layer material without deposition of appreciable amounts of copper on the copper layer already present.

It would be desirable to have a method that would allow selective deposition of materials onto a semiconductor surface that would not require the formation or use of a mask.

### SUMMARY OF THE INVENTION

One form of the present invention is a method for mask-less selective deposition made up of the steps of contacting a first portion of a substrate with a chemical agent that binds to the substrate to affect the susceptibility of the portion of the substrate to deposition. Following the treatment with the chemical agent, a first layer of a first material is deposited on a second portion of the substrate.

The first and second portions of the substrate may in fact be the same portion. That is to say, that the chemical agent may enhance or inhibit the deposition of the material of a portion of the substrate.

Another form of the invention is a method for mask-less selective deposition made up of the steps of contacting a first portion of a substrate with a chemical agent that binds to the substrate to enhance the susceptibility of the first portion of the substrate to deposition and depositing a first layer of a first material on the first portion of the substrate. Still another form of the present invention is a method for mask-less selective deposition made up of the steps of contacting a first portion of a substrate with a chemical agent that binds to the substrate to inhibit the susceptibility of the first portion of the substrate to deposition, and depositing of a first layer of a first material on a second portion of the substrate.

### BRIEF DESCRIPTION OF THE FIGURES

The above and further advantages of the invention may be better understood by referring to the following detailed description in conjunction with the accompanying drawings in which:

FIG. 1 depicts a schematic of a process in accordance with the present invention;

FIG. 2 depicts a graph of copper deposition before and after treatment in accordance with the present invention;

FIG. 3 depicts a sample before treatment in accordance with the present invention;

FIG. 4 depicts a sample following treatment in accordance with the present invention;

FIG. 5 depicts another view of the sample in FIG. 4;

FIG. 6 depicts another sample before and after treatment in accordance with the present invention; and

FIG. 7 depicts a scheme for selective deposition of copper contacts and interconnects in accordance with the present invention.

### DETAILED DESCRIPTION OF THE INVENTION

While the making and using of various embodiments of the present invention are discussed herein in terms of selective deposition of copper, it should be appreciated that the present invention provides many applicable inventive concepts that can be embodied in a wide variety of specific contexts. The specific embodiments discussed herein are merely illustrative of specific ways to make and use the invention and are not meant to limit the scope of the invention in any manner.

The present invention modifies the selectivity of a material's surface with respect to the ability of the surface to accept or reject the deposition of a material upon it. Such selectivity is accomplished through an appropriate chemical treatment or modification, altering the properties of the material surface.

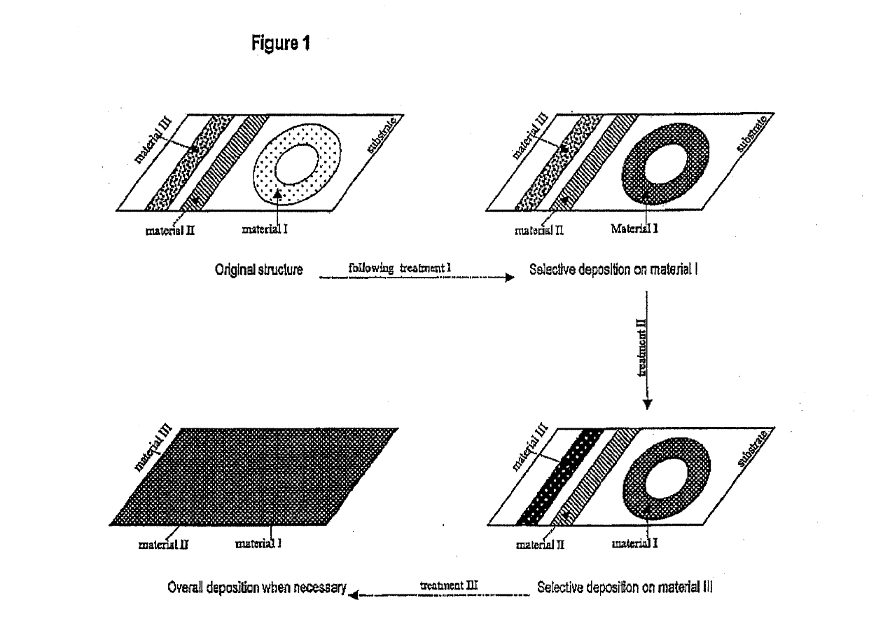

FIG. 1 depicts a schematic diagram illustrating the processes; In this example, three different materials share the same substrate. Without any treatment, deposition could occur simultaneously on all three materials. Through an appropriate surface treatment, however, deposition takes place on only one of them, such as material 1, as shown in FIG. 1.

Following another treatment, deposition on material III may be accomplished, and an overall deposition could occur on the entire surface after yet another treatment. It is of note that the source substance for each deposition does not have to be the same.

In general, all the materials and the substrate are subjected to the same treatment at the same time. Since different materials have different chemistry, they react differently to the same chemical treatment and, therefore, are differentiated from each other with respect to selective deposition. This is particularly important for certain applications including interconnect and contact formation for microelectronic fabrications.

The method of the present invention relies on the variation of chemistry on the material surface and does not require a mask, mold, stamp, templates or the like to be used in patterning or printing a desired structure on a substrate. Therefore, the present method does not suffer from the disadvantages of existing methods, such as lithography.

Once the surface chemistry of a given material has been modified, conventional methods including chemical vapor deposition (CVD), plasma vapor deposition (PVD), vacuum deposition (VD), sputtering deposition, and electrochemical plating can be used for the deposition.

The chemical treatment of the present invention involves absorption or reaction of certain chemical species on the material's surface to either activate or deactivate the surface toward a deposition. The absorbed species may be removed with a subsequent treatment to restore the original chemical properties of the material's surface.

Thus, the surface reactivity of a material may be turned on and off in a controlled manner, making it possible to select one material to be susceptible to deposition initially, and then for another material to be made susceptible subsequently.

Materials suitable for such treatment include metals, semiconductors, and insulators. An example of a chemical species for surface treatment are the alkane thiols, which feature variable chain lengths, and are capable of spontaneous absorption on the surface of a given material, such as copper, to modify its properties.

The treatment to passivate a material surface involves immersion of the sample, into a solution containing one or more chemical species for a certain period of time (seconds to days depending on the materials and the species). The material is reactivated by a treatment that removes the adsorbed species from the surface by methods including ultraviolet light irradiation, a potential (voltage) pulse application, chemical treatment, ion bombardment, high temperature treatment and the like.

### EXAMPLE 1

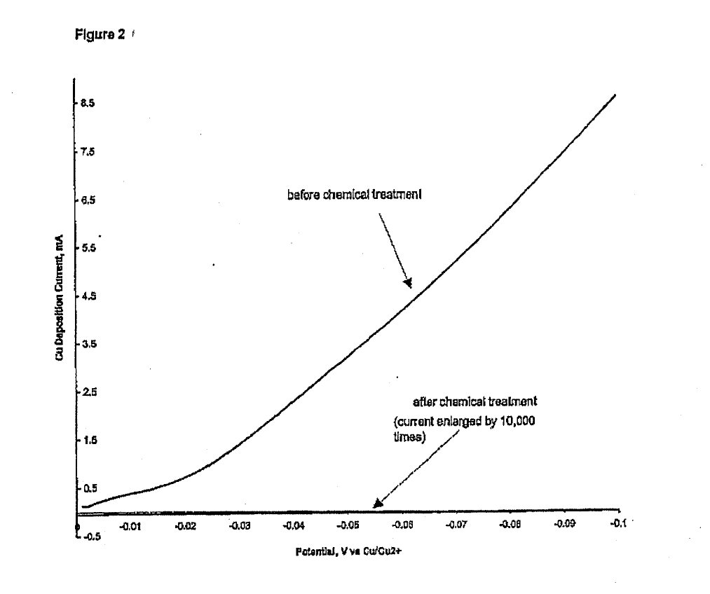

Electrochemical deposition of copper on a copper surface before and after the chemical treatment is shown in FIG. 2. The deposition was carried out in a solution of 1M CuSO₄ in water with a three-electrode system. Copper rods were used as both counter and reference electrodes. The scan rate was 20 mV/s. It can be seen that the deposition current was at ˜mA level for bare copper surface before chemical treatment and a uniform deposition of copper was seen with or without an optical microscope.

However, after the sample was immersed into a solution of ethanol containing 1 mM 1-dodecanethiol (98+%, Aldrich) overnight, the electrochemical deposition current diminished to negligible levels (the baseline) even after the current was amplified by 10,000 times under the same experimental conditions. No trace of copper deposition was observed under the optical microscope, indicating a successful suppression of copper deposition on copper surface by the chemical treatment.

### EXAMPLE 2

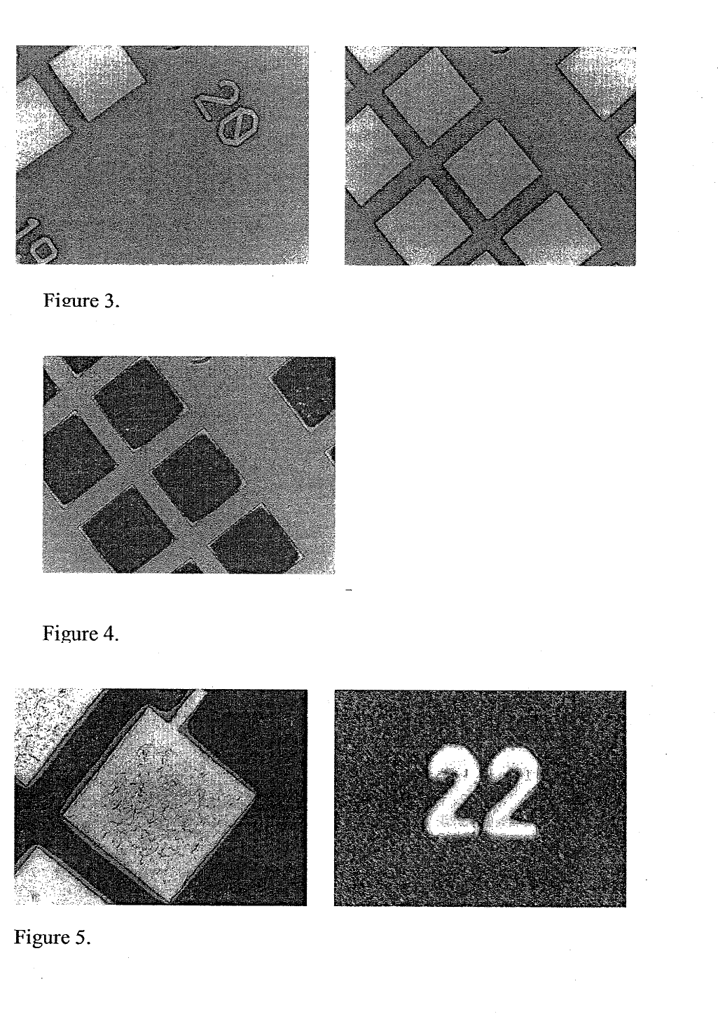

FIG. 3 shows images from a sample with copper structures surrounded by a barrier layer of tantalum. Without any chemical treatment, electrochemical deposition of copper occurred only on copper surface as shown in FIG. 4. When copper and barrier layers coexist on the same substrate, copper generally will deposit more easily on the copper surface.

FIG. 3 depicts images (382 μm×500 μm) from a sample that show copper structures surrounded by a barrier layer at two different locations. FIG. 4 depicts an image (382 μm×500 μm) of the same sample after copper deposition without pre-chemical treatment.

After the sample was immersed into a solution of ethanol containing 1 mM 1-dodecanethiol (98+%, Aldrich) for 4 hours, electrochemical deposition of copper occurred only on the barrier layer as shown in FIG. 5. In this case, the chemical absorption of the alkanethiol on the copper surface modified its properties and greatly decreased the rate of copper deposition on this surface, making it possible for copper deposition to occur preferentially on the barrier layer.

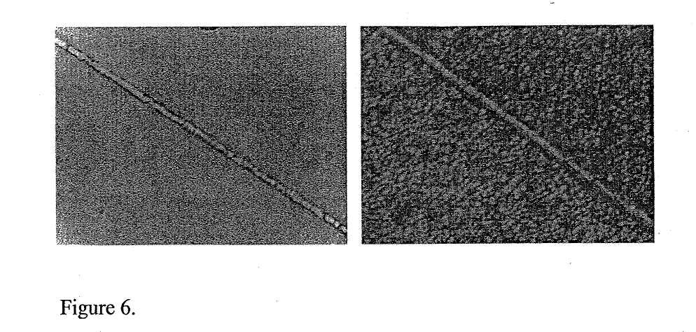

A similar result is seen on the micrometer scale as shown in FIG. 6. In this case, the less than one micrometer wide copper line clearly separates the two deposited copper zones, which are rough and higher than the copper line. These images demonstrate that the chemical treatment of the present invention for selective deposition functions well even on an extremely small scale.

### EXAMPLE 3

To demonstrate the reversibility of the chemical application, a negative potential was applied to the test surface. Specifically, after applying a negative potential pulse of 1.3V for 0.2 second, the chemically modified copper surface was restored to its original form.

This action removes the adsorbed chemical species and electrochemical deposition of copper on the reactivated copper layer was observed. Both the copper deposition current and the surface appearance were approximately the same as that observed for the original (untreated) copper surface. These results demonstrate the capability of the method of the present invention to reversibly alter the chemistry of a copper surface towards the copper deposition.

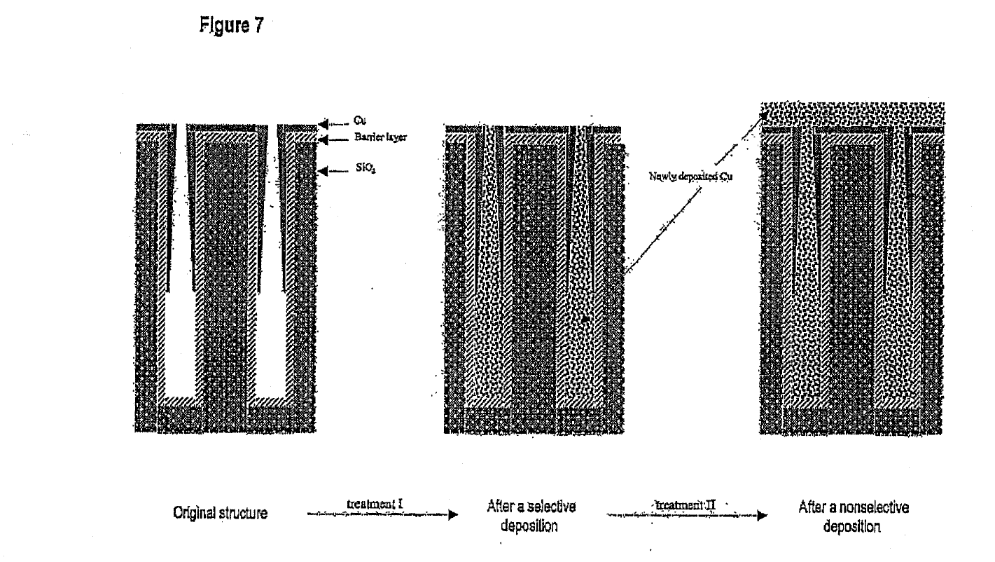

One particular application of the method of the present invention is to fabricate interconnects and contacts for electronic device as shown in FIG. 7. The leftmost image in FIG. 7 depicts a barrier layer that covers the surface of an SiO₂ substrate with a desired structure of trenches and vias. A copper layer produced by chemical vapor deposition (CVD) covers all locations except the bottoms and walls in the structure. This is a typical result due to technical limitations in uniform surface coverage into valleys and trenches using CVD. The gaps in the copper deposits will prevent formation of good copper contacts and interconnects in any subsequent electrodeposition step, given the tendency of copper to preferentially electrodeposit on the existing copper.

The method of the present invention can be used to fill the gaps in the trenches and vias with copper through a chemical treatment, so that copper may be selectively deposited on the bare barrier surface by electrochemical plating as shown in the center image in FIG. 7. Another treatment may then reverse the copper surface modification and deposit copper over the entire surface to complete the fabrication of contacts and interconnects.

Although this invention has been described and disclosed in relation to certain preferred embodiments, obvious equivalent modifications and alterations thereof will become apparent to one of ordinary skill in this art upon reading and understanding this specification and the claims appended hereto. Accordingly, the presently disclosed invention is intended to cover all such modifications and alterations, and is limited only by the scope of the claims that follow.

What is claimed:

1. A method for mask-less selective deposition comprising the steps:
contacting a first portion of a substrate with a chemical agent that binds to the substrate to affect the susceptibility of the first portion of the substrate to deposition; and
depositing of a first layer of a first material on a second portion of the substrate.

2. The method recited in claim 1, wherein the first and second portions are the same portion of the substrate.

3. The method recited in claim 1, wherein the contacting comprises immersion in a solution further comprising the chemical agent.

4. The method recited in claim 1, wherein the contacting comprises exposure to a vapor further comprising the chemical agent.

5. The method recited in claim 1, wherein the contacting inhibits deposition of the material on the first portion of the substrate.

6. The method recited in claim 1, wherein the contacting enhances deposition of the material on the first portion of the substrate.

7. The method recited in claim 1, wherein the chemical agent comprises a sulfur-containing compound.

8. The method recited in claim 1, wherein the chemical agent comprises an alkyl- or aryl-thiol compound.

9. The method recited in claim 8, wherein the thiol compound comprises 2 to 20 carbon atoms.

10. The method recited in claim 8, wherein the thiol compound comprises 10 to 50 carbon atoms.

11. The method recited in claim 8, wherein the thiol compound comprises dodecanethiol.

12. The method recited in claim 1, wherein the chemical agent comprises a disulfide compound.

13. The method recited in claim 1, wherein the depositing step comprises electrochemical deposition.

14. The method recited in claim 1, wherein the depositing step comprises chemical vapor deposition.

15. The method recited in claim 1, wherein the depositing step comprises plasma vapor deposition.

16. The method recited in claim 1, wherein the depositing step comprises vacuum deposition.

17. The method recited in claim 1, wherein the depositing step comprises sputtering deposition.

18. The method recited in claim 1, wherein the contacting activates the first portion of the substrate to deposition.

19. The method recited in claim 1, wherein the contacting deactivates the first portion of the substrate to deposition.

20. The method recited in claim 1, further comprising the step of reversal of the contacting.

21. The method recited in claim 20, wherein the reversal comprises removal of the chemical agent.

22. The method recited in claim 20, wherein the reversal comprises a reaction that neutralizes the effect of the chemical agent.

23. The method recited in claim 21, further comprising the step of depositing of a second layer of a second material.

24. The method recited in claim 23, wherein the first and second materials are the same material.

25. The method recited in claim 23, wherein the first and second layers are portions of the same layer.

26. The method recited in claim 1, wherein the substrate comprises a metal.

27. The method recited in claim 1, wherein the substrate comprises a semiconductor.

28. The method recited in claim 1, wherein the substrate comprises an insulator.

29. The method recited in claim 21, wherein the removal comprises exposure to a radiation source.

30. The method recited in claim 21, wherein the removal comprises exposure to ultraviolet light.

31. The method recited in claim 21, wherein the removal comprises exposure to a pulse application.

32. The method recited in claim 21, wherein the removal comprises exposure to ion bombardment.

33. The method recited in claim 21, wherein the removal comprises exposure to heat.

34. A method for mask-less selective deposition comprising the steps:
contacting a first portion of a substrate with a chemical agent that binds to the substrate to enhance the susceptibility of the first portion of the substrate to deposition; and
depositing of a first layer of a first material on the first portion of the substrate.

35. The method recited in claim 34, wherein the contacting comprises immersion in a solution further comprising the chemical agent.

36. A method for mask-less selective deposition comprising the steps:
contacting a first portion of a substrate with a chemical agent that binds to the substrate to inhibit the susceptibility of the first portion of the substrate to deposition; and
depositing of a first layer of a first material on a second portion of the substrate.

37. The method recited in claim 36, wherein the contacting comprises immersion in a solution further comprising the chemical agent.

38. The method recited in claim 36, wherein the chemical agent comprises a sulfur-containing compound.

39. The method recited in claim 36, wherein the chemical agent comprises an alkyl- or aryl-thiol compound.

40. The method recited in claim 39, wherein the thiol compound comprises 2 to 20 carbon atoms.

41. The method recited in claim 39, wherein the thiol compound comprises 10 to 50 carbon atoms.

42. The method recited in claim 39, wherein the thiol compound comprises dodecanethiol
